(19) United States
(12) Patent Application Publication
(10) Pub. No.: US 2026/0164733 A1
(43) Pub. Date: Jun. 11, 2026

(54) SEMICONDUCTOR DEVICE AND METHOD OF MANUFACTURING SEMICONDUCTOR DEVICE

(71) Applicant: Mitsubishi Electric Corporation, Tokyo (JP)

(72) Inventors: Kohei EBIHARA, Tokyo (JP); Masanori TSUKUDA, Tokyo (JP); Fumihito MASUOKA, Tokyo (JP)

(73) Assignee: Mitsubishi Electric Corporation, Tokyo (JP)

(21) Appl. No.: 19/348,455

(22) Filed: Oct. 2, 2025

(30) Foreign Application Priority Data
Dec. 11, 2024 (JP) 2024-216463

(51) Int. Cl. H10D 62/10; H01L 23/29; H01L 23/31; H10D 8/01; H10D 8/60; H10D 30/01

(52) U.S. Cl. CPC H10D 62/107; H10D 8/051; H10D 8/60; H10D 30/027; H10W 74/137; H10W 74/147; H10W 74/43

(57) ABSTRACT

A semiconductor device includes: a first insulating film provided on a semiconductor layer, having a first opening that exposes an impurity region, and containing SiO₂ as a main component; a second insulating film provided on the first insulating film, having a second opening that exposes the impurity region, and containing SiO₂ as a main component; and a semi-insulating film provided on the second insulating film and connected to the impurity region via the first opening and the second opening, in which a width of the second opening is larger than a width of the first opening.

### BACKGROUND

### Technical Field

The present disclosure relates to a semiconductor device and a method of manufacturing a semiconductor device.

### Description of the Background Art

In a general semiconductor device, the potential of a termination region that is an outer peripheral portion surrounding a semiconductor element is stabilized by providing a metal electrode made of aluminum or the like on a guard ring that is an impurity region, but there is a problem that the metal electrode is likely to corrode and peel off. Therefore, a configuration in which, instead of the metal electrode, a semi-insulating film that is less likely to peel off than the metal electrode is used has recently been proposed (e.g., Japanese Unexamined Patent Application Publication (Translation of PCT Application) No. 2018-504778).

However, even in the configuration in which the semi-insulating film is used, there is a problem that the semi-insulating film may peel off.

### SUMMARY

The present disclosure has been made in view of the above problems, and an object thereof is to provide a technique capable of suppressing peeling off of a semi-insulating film.

A semiconductor device according to the present disclosure includes: a semiconductor layer having a first conductivity type; a semiconductor element provided in the semiconductor layer; an impurity region having a second conductivity type and selectively provided in an upper portion of an outer peripheral portion of the semiconductor layer that surrounds the semiconductor element; a first insulating film provided on the semiconductor layer, having a first opening that exposes the impurity region, and containing SiO₂ as a main component; a second insulating film provided on the first insulating film, having a second opening that exposes the impurity region, and containing SiO₂ as a main component; and a semi-insulating film provided on the second insulating film and connected to the impurity region via the first opening and the second opening, in which the impurity region includes at least one of a guard ring and a floating ring, and a width of the second opening is larger than a width of the first opening.

Peeling off of the semi-insulating film can be suppressed.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a cross-sectional view illustrating a configuration of an end portion of a semiconductor device according to a first preferred embodiment;

FIG. 2 is a cross-sectional view illustrating a configuration of an end portion of a semiconductor device according to a first modification of the first preferred embodiment;

FIG. 3 is a cross-sectional view illustrating a configuration of an end portion of a semiconductor device according to a second modification of the first preferred embodiment;

FIG. 4 is a cross-sectional view illustrating a configuration of an end portion of a semiconductor device according to a third modification of the first preferred embodiment;

FIG. 5 is a cross-sectional view illustrating a configuration of an end portion of a semiconductor device according to a fourth modification of the first preferred embodiment;

FIG. 6 is a cross-sectional view illustrating a configuration of an end portion of a semiconductor device according to a fifth modification of the first preferred embodiment;

FIG. 7 is a cross-sectional view illustrating a configuration of an end portion of a semiconductor device according to a seventh modification of the first preferred embodiment;

FIG. 8 is a cross-sectional view illustrating a configuration of an end portion of a semiconductor device according to a second preferred embodiment;

FIG. 9 is a cross-sectional view illustrating a configuration of an end portion of a semiconductor device according to a first modification of the second preferred embodiment;

FIG. 10 is a cross-sectional view illustrating a configuration of an end portion of a semiconductor device according to a second modification of the second preferred embodiment;

FIG. 11 is a cross-sectional view illustrating a configuration of an end portion of a semiconductor device according to a third modification of the second preferred embodiment;

FIG. 12 is a cross-sectional view illustrating a configuration of an end portion of a semiconductor device according to a fourth modification of the second preferred embodiment; and

FIG. 13 is a cross-sectional view illustrating a configuration of an end portion of a semiconductor device according to a third preferred embodiment.

### DESCRIPTION OF THE PREFERRED EMBODIMENTS

Hereinafter, preferred embodiments will be described with reference to the accompanying drawings. Features described in each of the following embodiments are examples, and all features are not necessarily essential. In the following description, similar components in a plurality of preferred embodiments are denoted by the same or similar reference numerals, and different components will be mainly described. In addition, in the following description, specific positions and directions, such as “upper”, “lower”, “left”, “right”, “front”, or “back”, may not necessarily coincide with actual positions and directions in practice. In addition, the fact that a certain portion has a higher concentration than another portion may mean that, for example, the average or peak of the concentration in the certain portion is higher than the average or peak of the concentration in another portion. Conversely, the fact that a certain portion has a lower concentration than another portion may mean that, for example, the average or peak of the concentration in the certain portion is lower than the average or peak of the concentration in another portion. In addition, in the following description, the first conductivity type is an n-type and the second conductivity type is a p-type, but the first conductivity type may be a p-type and the second conductivity type may be an n-type.

### First Preferred Embodiment

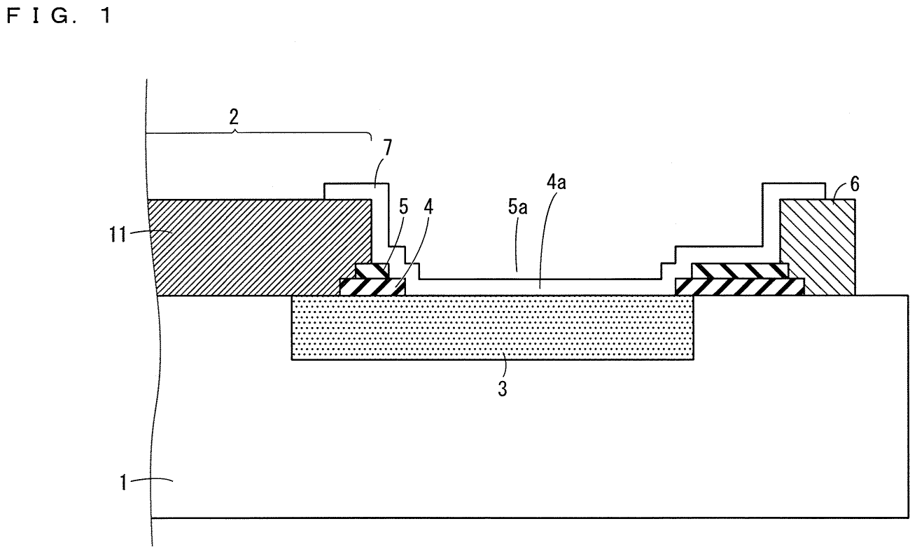

FIG. 1 is a cross-sectional view illustrating a configuration of an end portion of a semiconductor device according to a first preferred embodiment. The semiconductor device of FIG. 1 includes a semiconductor layer 1, a semiconductor element 2, a guard ring 3, a first insulating film 4, a second insulating film 5, an outer peripheral electrode 6, and a semi-insulating film 7.

The semiconductor layer 1 has an n-type. The semiconductor layer 1 may be made of silicon (Si), or may be made of a wide band gap semiconductor such as silicon carbide (SiC), gallium nitride (GaN), gallium oxide (Ga₂O₃), or diamond. In a case where the semiconductor layer 1 is made of a wide band gap semiconductor, it is possible to stably operate the semiconductor device at a high temperature and at a high voltage and to increase the switching speed. The semiconductor layer 1 may be made of a semiconductor wafer or an epitaxial growth layer.

The semiconductor element 2 is provided in the semiconductor layer 1. The semiconductor element 2 according to the first preferred embodiment is a Schottky barrier diode including the semiconductor layer 1 and a surface electrode 11, but it is not limited thereto as described later. A portion of the semiconductor layer 1, where the semiconductor element 2 is provided, is an element region. An outer peripheral portion of the semiconductor layer 1 that surrounds the semiconductor element 2 is a termination region.

The guard ring 3 is selectively provided in the upper portion of the outer peripheral portion of the semiconductor layer 1 that surrounds the semiconductor element 2, that is, selectively provided in the upper portion of the termination region, and is an impurity region having a p-type. The guard ring 3 is electrically connected to the surface electrode 11 regardless of the presence or absence of the semi-insulating film 7.

The first insulating film 4 is provided on the semiconductor layer 1 and has a first opening 4a that exposes the guard ring 3. The first insulating film 4 contains SiO₂ as a main component.

The second insulating film 5 is provided on the first insulating film 4 and has a second opening 5a that exposes the guard ring 3. The width of the second opening 5a is larger than the width of the first opening 4a. The second insulating film 5 contains SiO₂ as a main component similarly to the first insulating film 4.

The outer peripheral electrode 6 is provided on portions of the semiconductor layer 1, the first insulating film 4, and the second insulating film 5 close to an outside of the semiconductor layer 1. In the first preferred embodiment, the thickness of the outer peripheral electrode 6 is larger than the thickness of each of the first insulating film 4 and the second insulating film.

The surface electrode 11 is provided on portions of the semiconductor layer 1, the first insulating film 4, and the second insulating film 5 close to the element region. In the first preferred embodiment, the thickness of the surface electrode 11 is larger than the thickness of each of the first insulating film 4 and the second insulating film 5.

The semi-insulating film 7 is provided on at least the second insulating film 5, and is connected to the guard ring 3 via the first opening 4a and the second opening 5a. The semi-insulating film 7 may be made of, for example, SiN whose conductivity is increased by increasing the ratio of Si such as SinSiN (Semi-insulated SiN), or may be made of SIPOS (Semi-insulating polycrystalline-silicon). In the first preferred embodiment, SinSiN is used as the material of the semi-insulating film 7, and its resistivity is, for example, less than 1×10¹² Ω·cm.

### <Manufacturing Method>

Next, an example of a manufacturing method of the semiconductor device according to the first preferred embodiment will be described. First, the guard ring 3 is formed by implanting ions into the semiconductor layer 1. Then, the first insulating film 4 is formed by thermal oxidation, and the second insulating film 5 is formed by chemical vapor deposition (CVD). The CVD is preferably plasma CVD, but is not limited thereto.

Thereafter, the first opening 4a and the second opening 5a are formed in parallel with the first insulating film 4 and the second insulating film 5, respectively, by wet etching. Then, the semi-insulating film 7 is formed by CVD.

### <Summary of First Preferred Embodiment>

In a configuration in which the semi-insulating film 7 is not provided, a high electric field is applied to the periphery of the guard ring 3 at the time of reverse bias to generate charges, and as a result, the potential may become unstable. On the other hand, in the configuration in which the semi-insulating film 7 connected to the guard ring 3 is provided as in the first preferred embodiment, the charge generated around the guard ring 3 at the time of reverse bias can be discharged by the semi-insulating film 7, so that the potential around the guard ring 3 can be stabilized.

In addition, in the first preferred embodiment, the width of the second opening 5a is larger than the width of the first opening 4a. According to such a configuration, the rise of the cross-sectional shape from the semiconductor layer 1 to the upper portion of the outer peripheral electrode 6 or the surface electrode 11 becomes gentle. For this reason, the bent shape of the semi-insulating film 7 in the cross-sectional view can be suppressed, so that it is possible to suppress occurrence of a crack in the semi-insulating film 7 due to the stress generated by temperature humidity bias (THB) or the like. As a result, peeling off of the semi-insulating film 7 can be suppressed, and the reliability of the semiconductor device can be enhanced. Note that, in a case where the thickness of the first insulating film 4 is smaller than the thickness of the second insulating film 5, the rise of the cross-sectional shape becomes gentler, so that the reliability of the semiconductor device can be further enhanced.

In addition, in the first preferred embodiment, each of the first insulating film 4 and the second insulating film 5 contains SiO₂ as a main component, so that the stress on the semi-insulating film 7 can be reduced, and peeling off of the semi-insulating film 7 can be suppressed.

In addition, in the first preferred embodiment, the first opening 4a and the second opening 5a are formed in parallel with the first insulating film 4 and the second insulating film 5, respectively, by wet etching, so that it is possible to easily form a semiconductor device with enhanced reliability.

### <First Modification of First Preferred Embodiment>

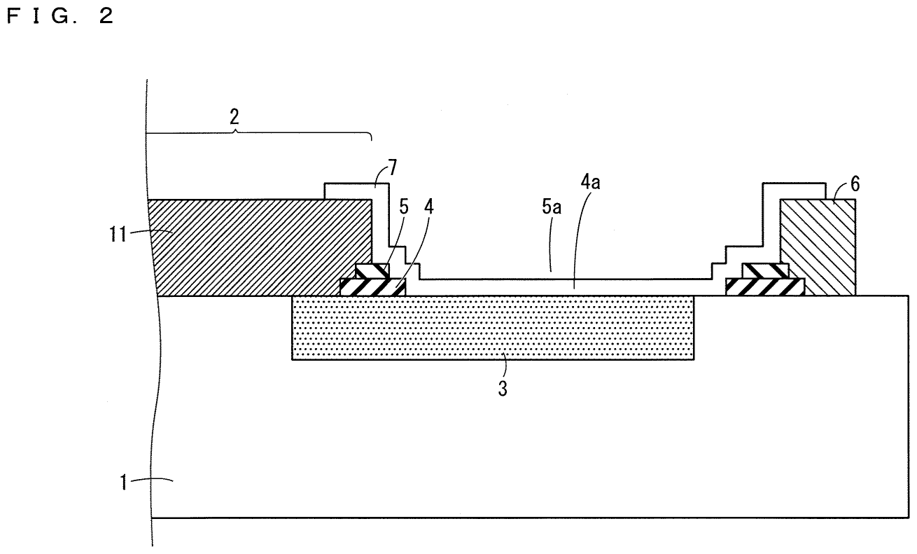

FIG. 2 is a cross-sectional view illustrating a configuration of an end portion of a semiconductor device according to a first modification. In the first modification, an end of the first opening 4a located close to the outside of the semiconductor layer 1 is located closer to the outside of the semiconductor layer 1 than an end of the guard ring 3 located close to the outside of the semiconductor layer 1 is. According to such a configuration, the semi-insulating film 7 is connected not only to the guard ring 3 but also to the semiconductor layer 1 adjacent to the outer end of the guard ring 3, so that the potential gradient at the boundary between the guard ring 3 and the semiconductor layer 1 can be made gentle, and the charges generated by the high electric field of the outer periphery of the guard ring 3 can be discharged by the semi-insulating film 7. As a result, the withstand voltage of the semiconductor device can be enhanced.

### <Second Modification of First Preferred Embodiment>

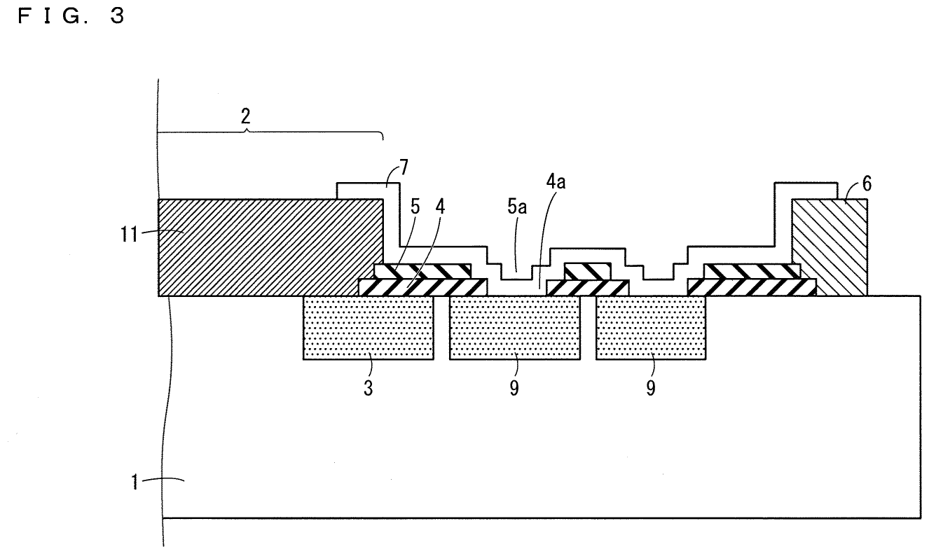

FIG. 3 is a cross-sectional view illustrating a configuration of an end portion of a semiconductor device according to a second modification. The p-type impurity region connected to the semi-insulating film 7 is the guard ring 3 in the above description, but is a floating ring 9 in the second modification. The floating ring 9 is different from the guard ring 3 in that, in a case where the semi-insulating film 7 is not provided, the floating ring 9 is not electrically connected to the surface electrode 11 and the potential of the floating ring 9 floats. In the second modification, the floating ring 9 is electrically connected to the surface electrode 11 to some extent by the semi-insulating film 7, so that the potential around the floating ring 9 can be stabilized.

### <Third Modification of First Preferred Embodiment>

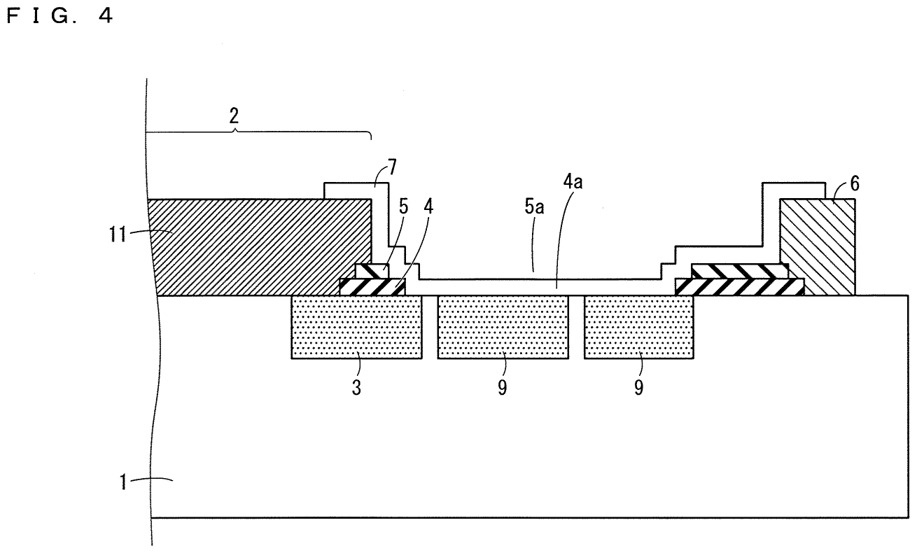

FIG. 4 is a cross-sectional view illustrating a configuration of an end portion of a semiconductor device according to a third modification. In the third modification, the p-type impurity regions connected to the semi-insulating film 7 are a guard ring 3 and a floating ring 9 that are spaced apart from each other. The first opening 4a is provided across the guard ring 3 and the floating ring 9. According to such a configuration, the semi-insulating film 7 is connected not only to the guard ring 3 and the floating ring 9 but also to the semiconductor layer 1 adjacent to them, so that the potential gradient at the boundary between each of the guard ring 3 and the floating ring 9 and the semiconductor layer 1 can be made gentle, and the charges generated by the high electric field of the outer periphery of each of the guard ring 3 and the floating ring 9 can be discharged by the semi-insulating film 7. As a result, the withstand voltage of the semiconductor device can be enhanced.

### <Fourth Modification of First Preferred Embodiment>

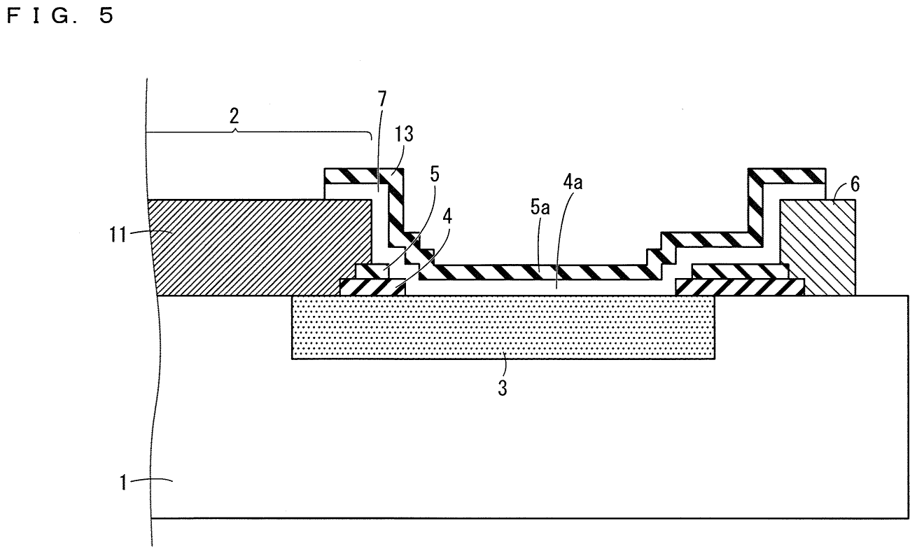

FIG. 5 is a cross-sectional view illustrating a configuration of an end portion of a semiconductor device according to a fourth modification. In the fourth modification, a moisture-resistant insulating film 13 provided on the semi-insulating film 7 is added. The moisture-resistant insulating film 13 may be made of, for example, SiN whose conductivity is reduced by reducing the ratio of Si. According to such a configuration, deterioration of the semiconductor layer 1, the first insulating film 4, the second insulating film 5, and the semi-insulating film 7 due to a reaction with moisture from the outside can be suppressed by the moisture-resistant insulating film 13, so that the reliability of the semiconductor device can be enhanced. In the fourth modification, the resistivity of SiN that is the material of the moisture-resistant insulating film 13 is, for example, 1×10¹² Ω·cm or more.

### <Fifth Modification of First Preferred Embodiment>

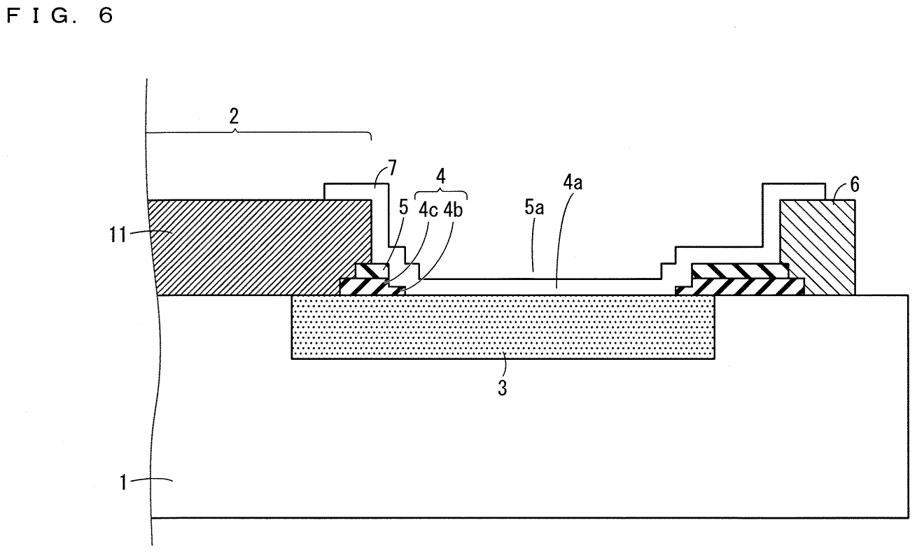

FIG. 6 is a cross-sectional view illustrating a configuration of an end portion of a semiconductor device according to a fifth modification. In the fifth modification, a first portion 4b of the first insulating film 4 located under the second opening 5a is thinner than a second portion 4c of the first insulating film 4 other than the first portion 4b. According to such a configuration, the rise of the cross-sectional shape from the semiconductor layer 1 to the upper portion of the outer peripheral electrode 6 or the surface electrode 11 becomes gentler, so that the reliability of the semiconductor device can be further enhanced.

### <Sixth Modification of First Preferred Embodiment>

The density of the second insulating film 5 may be smaller than the density of the first insulating film 4. In an insulating film containing SiO₂ as a main component, the speed of wet etching generally increases as the density [g/cm³] decreases. Therefore, a configuration in which the width of the second opening 5a of the second insulating film 5 is larger than the width of the first opening 4a of the first insulating film 4, and the first insulating film 4 as illustrated in FIG. 6 of the fifth modification can be easily formed.

In addition, each of the first insulating film 4 and the second insulating film 5 may further contain phosphorus, and the concentration of phosphorus in the second insulating film 5 may be higher than the concentration of phosphorus in the first insulating film 4. In an insulating film containing SiO₂ as a main component, the speed of wet etching generally increases as the concentration of phosphorus increases. Therefore, a configuration in which the width of the second opening 5a of the second insulating film 5 is larger than the width of the first opening 4a of the first insulating film 4, and the first insulating film 4 as illustrated in FIG. 6 of the fifth modification can be easily formed.

### <Seventh Modification of First Preferred Embodiment>

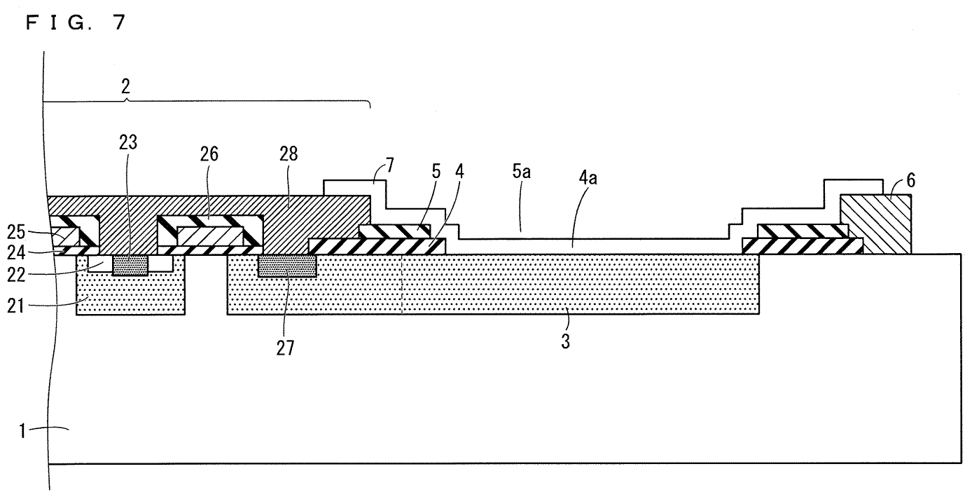

FIG. 7 is a cross-sectional view illustrating a configuration of an end portion of a semiconductor device according to a seventh modification. The semiconductor element 2 is a Schottky barrier diode in the above description, but is a planar type MOSFET (Metal Oxide Semiconductor Field Effect Transistor) in the seventh modification. The semiconductor element 2 in FIG. 7 includes a semiconductor layer 1, a p-type base layer 21, an n-type source layer 22, a p⁺-type contact layer 23, a gate insulating film 24, a gate electrode 25, an interlayer insulating film 26, a p⁺-type well layer 27, and a surface electrode 28.

The p-type base layer 21 is selectively provided in the upper portion of the semiconductor layer 1. The n-type source layer 22 is selectively provided in the upper portion of the p-type base layer 21 so as to sandwich the upper portion of the p-type base layer 21 with the upper portion of the semiconductor layer 1. The p⁺-type contact layer 23 is selectively provided in the upper portion of the p-type base layer 21 adjacent to the n-type source layer 22, and the p-type impurity concentration of the p⁺-type contact layer 23 is higher than the p-type impurity concentration of the p-type base layer 21.

The gate electrode 25 is provided above the p-type base layer 21 sandwiched between the semiconductor layer 1 and the n-type source layer 22 via the gate insulating film 24. The interlayer insulating film 26 is provided to cover the gate electrode 25. The p⁺-type well layer 27 is provided closer to the outside of the semiconductor layer 1 than the gate electrode 25 is, and the p-type impurity concentration of the p⁺-type well layer 27 is higher than the p-type impurity concentration of the p-type base layer 21. The surface electrode 28 is provided on the interlayer insulating film 26 and is connected to the n-type source layer 22, the p⁺-type contact layer 23, and the p⁺-type well layer 27 via a contact hole.

In the above configuration, when a voltage equal to or higher than the threshold voltage is applied to the gate electrode 25, a channel that can allow a current to flow between the semiconductor layer 1 and the surface electrode 28 is formed in the upper portion of the p-type base layer 21. As described above, even in a case where the semiconductor element 2 is a planar type MOSFET, the rise of the cross-sectional shape from the semiconductor layer 1 to the upper portion of the outer peripheral electrode 6 or the surface electrode 11 becomes gentle, so that the reliability of the semiconductor device can be enhanced. Note that the semiconductor element 2 is not limited to the above, and may be a trench type MOSFET, an IGBT (Insulated Gate Bipolar Transistor), a RC-IGBT (Reverse Conducting-IGBT), or a PND (PN junction diode).

### Second Preferred Embodiment

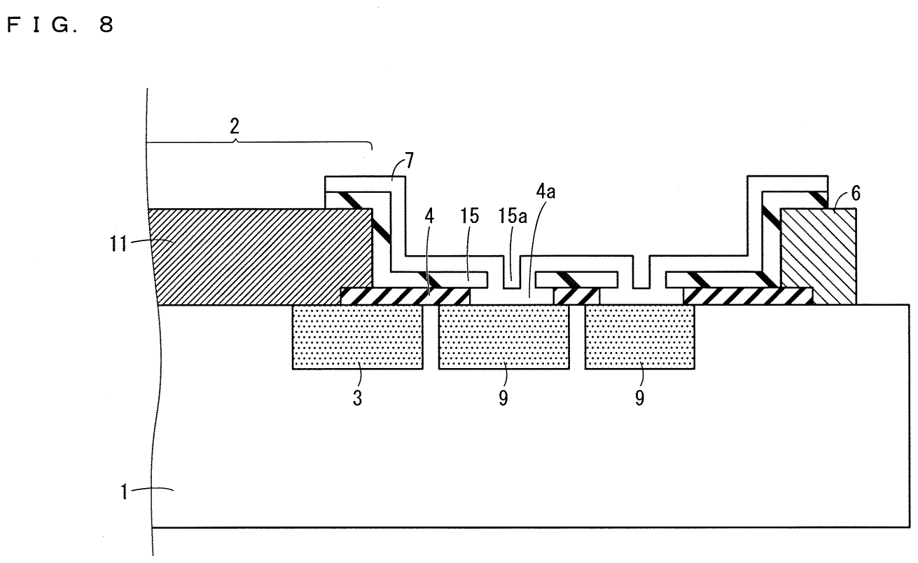

FIG. 8 is a cross-sectional view illustrating a configuration of an end portion of a semiconductor device according to a second preferred embodiment. The semiconductor device of FIG. 8 includes a semiconductor layer 1, a semiconductor element 2, a guard ring 3, a first insulating film 4, an outer peripheral electrode 6, a semi-insulating film 7, a floating ring 9, and a non-metallic film 15.

Note that the semiconductor layer 1, the semiconductor element 2, the guard ring 3, the outer peripheral electrode 6, and the floating ring 9 are substantially the same as those described above. The semiconductor element 2 is a Schottky barrier diode including the semiconductor layer 1 and a surface electrode 11 as in the first preferred embodiment, but may be a MOSFET, an IGBT, an RC-IGBT, or a PND as in the seventh modification of the first preferred embodiment.

The first insulating film 4 is provided on the semiconductor layer 1 and has a first opening 4a that exposes the floating ring 9. Note that the first insulating film 4 may or may not contain SiO₂ as a main component.

The non-metallic film 15 is provided on at least the first insulating film 4 and has a second opening 15a that exposes the floating ring 9. The width of the second opening 15a is smaller than the width of the first opening 4a. The non-metallic film 15 has an insulating property or a semi-insulating property. The non-metallic film 15 having an insulating property may be made of, for example, SiN whose conductivity is reduced by reducing the ratio of Si. The non-metallic film 15 having a semi-insulating property may be made of, for example, SiN whose conductivity is increased by increasing the ratio of Si such as SinSiN, or may be made of SIPOS. The resistivity of the non-metallic film 15 having an insulating property is, for example, 1×10¹² Ω·cm or more, and the resistivity of the non-metallic film 15 having a semi-insulating property is, for example, less than 1×10¹² Ω·cm.

The semi-insulating film 7 is provided on the non-metallic film 15, and is connected to the floating ring 9 via the first opening 4a and the second opening 15a. The semi-insulating film 7 may be made of, for example, SiN whose conductivity is increased by increasing the ratio of Si such as SinSiN, or may be made of SIPOS. Note that in a case where the non-metallic film 15 has an insulating property, the semi-insulating film 7 is also provided on the outer peripheral electrode 6 and the surface electrode 11.

### <Manufacturing Method>

Next, an example of a manufacturing method of the semiconductor device according to the second preferred embodiment will be described. First, the guard ring 3 and the floating ring 9 are formed by implanting ions into the semiconductor layer 1. Then, the first insulating film 4 is formed by thermal oxidation, and the non-metallic film 15 having a wet etching speed lower than that of the first insulating film 4 is formed by CVD. For example, in a case where the first insulating film 4 contains SiO₂ as a main component, an SiN film is used for the non-metallic film 15 having a wet etching speed lower than that of the first insulating film 4.

Thereafter, the second opening 15a is formed in the non-metallic film 15 by dry etching, and the first opening 4a is formed in the first insulating film 4 by wet etching. Then, the semi-insulating film 7 is formed by CVD.

### <Summary of Second Preferred Embodiment>

According to the semiconductor device according to the second preferred embodiment as described above, the semi-insulating film 7 connected to the floating ring 9 is provided as in the first preferred embodiment, so that the potential around the floating ring 9 can be stabilized.

In addition, in the second preferred embodiment, the width of the second opening 15a is smaller than the width of the first opening 4a. According to such a configuration, a part of the non-metallic film 15 serves as an eaves portion, and peeling off of the semi-insulating film 7 under the eaves portion can be suppressed by an anchor effect, so that the reliability of the semiconductor device can be enhanced.

In addition, in the second preferred embodiment, the second opening 15a is formed in the non-metallic film 15 by dry etching, and the first opening 4a is formed in the first insulating film 4 by wet etching. According to such a configuration, the first insulating film 4 is present on the floating ring 9 during the dry etching of the non-metallic film 15, so that damage to the floating ring 9 due to the dry etching can be suppressed.

### <First Modification of Second Preferred Embodiment>

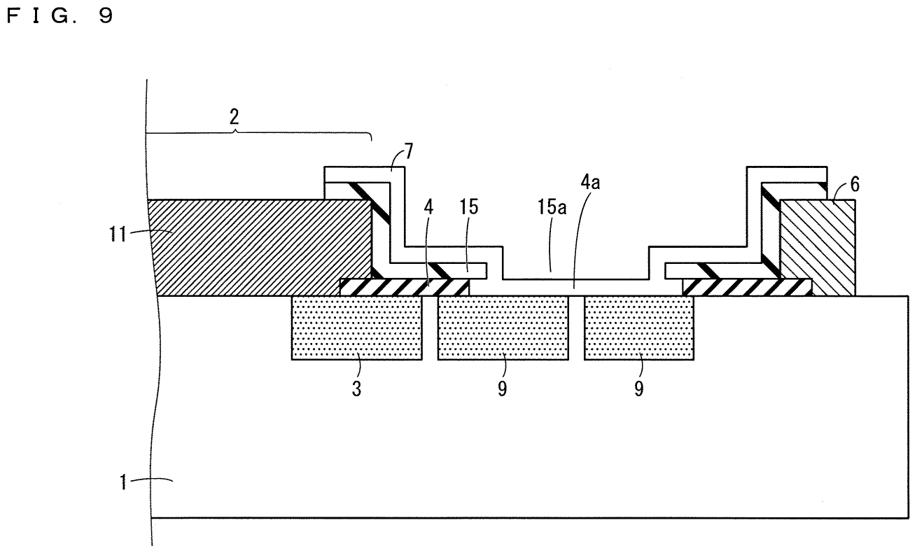

FIG. 9 is a cross-sectional view illustrating a configuration of an end portion of a semiconductor device according to a first modification. In the first modification, a p-type impurity region connected to the semi-insulating film 7 is a plurality of floating rings 9 spaced apart from each other. The first opening 4a is provided across the plurality of floating rings 9. According to such a configuration, the semi-insulating film 7 is connected not only to the floating ring 9 but also to the semiconductor layer 1 adjacent to the floating ring 9, so that the potential gradient at the boundary between the floating ring 9 and the semiconductor layer 1 can be made gentle, and the charges generated by the high electric field of the outer periphery of each of the plurality of floating rings 9 can be discharged by the semi-insulating film 7. As a result, the withstand voltage of the semiconductor device can be enhanced.

### <Second Modification of Second Preferred Embodiment>

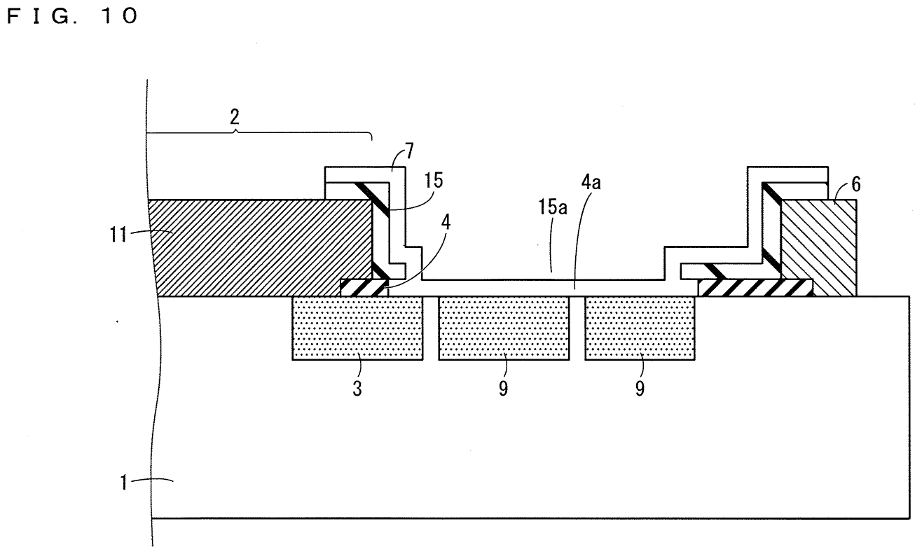

FIG. 10 is a cross-sectional view illustrating a configuration of an end portion of a semiconductor device according to a second modification. In the second modification, the p-type impurity region connected to the semi-insulating film 7 is a guard ring 3 and a floating ring 9 that are spaced apart from each other. The first opening 4a is provided across the guard ring 3 and the floating ring 9. According to such a configuration, the semi-insulating film 7 is connected not only to the guard ring 3 and the floating ring 9 but also to the semiconductor layer 1 adjacent to them, so that the potential gradient at the boundary between each of the guard ring 3 and the floating ring 9 and the semiconductor layer 1 can be made gentle, and the charges generated by the high electric field of the outer periphery of each of the guard ring 3 and the floating ring 9 can be discharged by the semi-insulating film 7. As a result, the withstand voltage of the semiconductor device can be enhanced.

### <Third Modification of Second Preferred Embodiment>

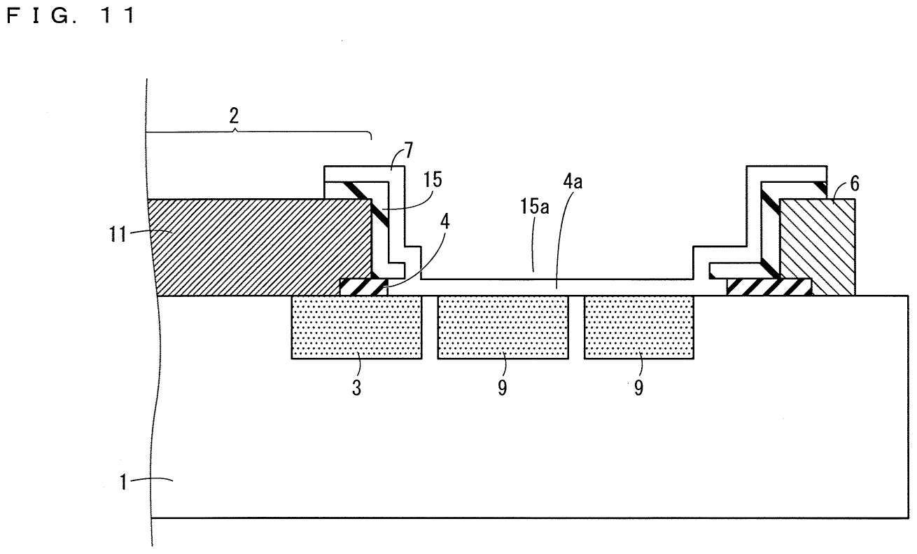

FIG. 11 is a cross-sectional view illustrating a configuration of an end portion of a semiconductor device according to a third modification. In the third modification, an end of the first opening 4a located close to the outside of the semiconductor layer 1 is located closer to the outside of the semiconductor layer 1 than an end of the floating ring 9 located close to the outside of the semiconductor layer 1 is. According to such a configuration, the semi-insulating film 7 is connected not only to the floating ring 9 but also to the semiconductor layer 1 adjacent to the outer end of the floating ring 9, so that the potential gradient at the boundary between the floating ring 9 and the semiconductor layer 1 can be made gentle, and the charges generated by the high electric field of the outer periphery of the floating ring 9 can be discharged by the semi-insulating film 7. As a result, the withstand voltage of the semiconductor device can be enhanced.

### <Fourth Modification of Second Preferred Embodiment>

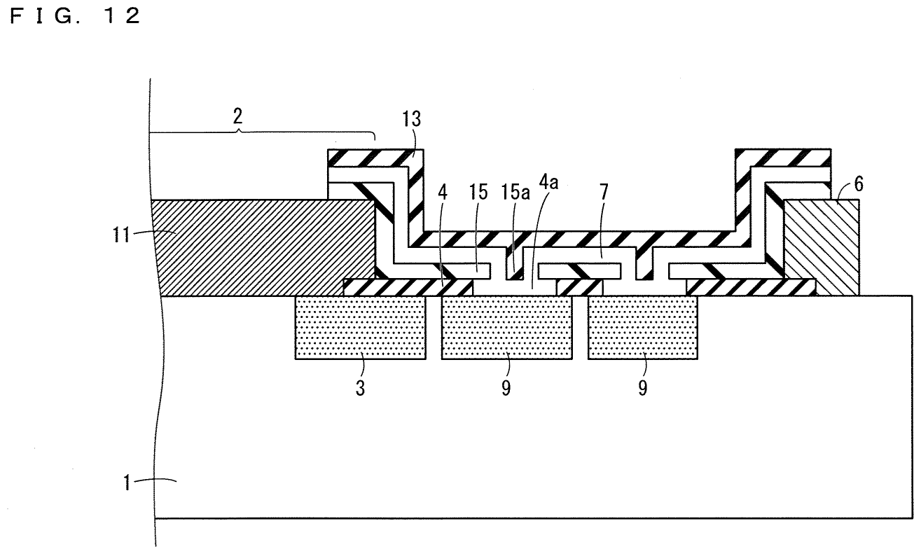

FIG. 12 is a cross-sectional view illustrating a configuration of an end portion of a semiconductor device according to a fourth modification. In the fourth modification, a moisture-resistant insulating film 13 provided on the semi-insulating film 7 is added. The moisture-resistant insulating film 13 may be made of, for example, SiN whose conductivity is reduced by reducing the ratio of Si. According to such a configuration, deterioration of the semiconductor layer 1, the first insulating film 4, the semi-insulating film 7, and the non-metallic film 15 due to a reaction with moisture from the outside can be suppressed by the moisture-resistant insulating film 13, so that the reliability of the semiconductor device can be enhanced.

### Third Preferred Embodiment

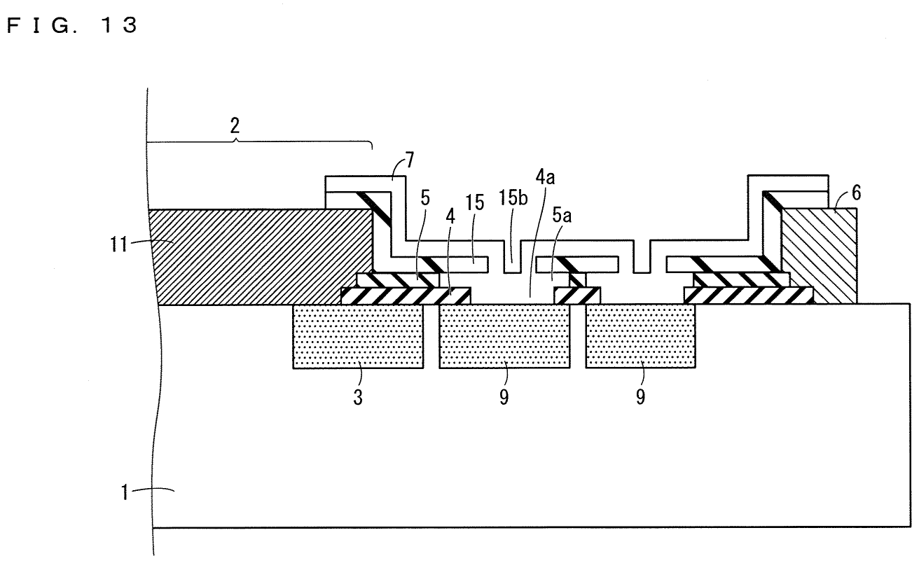

FIG. 13 is a cross-sectional view illustrating a configuration of an end portion of a semiconductor device according to a third preferred embodiment. The semiconductor device of FIG. 13 is similar to a configuration in which the second insulating film 5 of the first preferred embodiment is added to the configuration of FIG. 8 of the second preferred embodiment.

Specifically, the second insulating film 5 is provided on the first insulating film 4 and has a second opening 5a that exposes the floating ring 9. The width of the second opening 5a of the second insulating film 5 is larger than the width of the first opening 4a of the first insulating film 4. Note that the second insulating film 5 may or may not contain SiO₂ as a main component.

The non-metallic film 15 is provided on at least the second insulating film 5, and has a third opening 15b corresponding to the second opening 15a according to the second preferred embodiment. The width of the third opening 15b of the non-metallic film 15 is smaller than the width of the second opening 5a of the second insulating film 5.

The semi-insulating film 7 is provided on the non-metallic film 15, and is connected to the floating ring 9 via the first opening 4a, the second opening 5a, and the third opening 15b. Note that in a case where the non-metallic film 15 has an insulating property, the semi-insulating film 7 is also provided on the outer peripheral electrode 6 and the surface electrode 11.

### <Manufacturing Method>

Next, an example of a manufacturing method of the semiconductor device according to the third preferred embodiment will be described. First, the guard ring 3 and the floating ring 9 are formed by implanting ions into the semiconductor layer 1. Then, the first insulating film 4 is formed by thermal oxidation, the second insulating film 5 is formed by CVD, and the non-metallic film 15 having a wet etching speed lower than those of the first insulating film 4 and the second insulating film 5 is formed by CVD. For example, in a case where each of the first insulating film 4 and the second insulating film 5 contains SiO₂ as a main component, an SiN film is used for the non-metallic film 15 having a wet etching speed lower than those of the first insulating film 4 and the second insulating film 5.

Thereafter, the third opening 15b is formed in the non-metallic film 15 by dry etching, and the first opening 4a and the second opening 5a are formed in parallel with the first insulating film 4 and the second insulating film 5, respectively, by wet etching. Then, the semi-insulating film 7 is formed by CVD.

### <Summary of Third Preferred Embodiment>

According to the semiconductor device according to the third preferred embodiment as described above, the semi-insulating film 7 connected to the floating ring 9 is provided as in the second preferred embodiment, so that the potential around the floating ring 9 can be stabilized.

In addition, in the third preferred embodiment, the width of the second opening 5a of the second insulating film 5 is larger than the width of the first opening 4a of the first insulating film 4, so that occurrence of a crack in the semi-insulating film 7, and eventually peeling off of the semi-insulating film 7 can be suppressed as in the first preferred embodiment. In addition, in the third preferred embodiment, the width of the third opening 15b of the non-metallic film 15 is smaller than the width of the second opening 5a of the second insulating film 5, so that peeling off of the semi-insulating film 7 can be suppressed by an anchor effect. As a result, the reliability of the semiconductor device can be enhanced.

In addition, in the third preferred embodiment, the third opening 15b is formed in the non-metallic film 15 by dry etching, and the first opening 4a and the second opening 5a are formed by wet etching, so that damage to the floating ring 9 due to dry etching can be suppressed. In addition, the first opening 4a and the second opening 5a are formed in parallel with the first insulating film 4 and the second insulating film 5, respectively, by wet etching, so that it is possible to easily form a semiconductor device with enhanced reliability.

### <Modification of Third Preferred Embodiment>

At least one of the modifications of the first preferred embodiment and the modifications of the second preferred embodiment may be applied to the third preferred embodiment.

In the present disclosure in English, ‘a’ and ‘an’ mean one or more. Thus, ‘a’, ‘an’, ‘one or more’ and ‘at least one’ can be used interchangeably.

Note that respective preferred embodiments and respective modifications can be freely combined, and each preferred embodiment and each modification can be appropriately modified or omitted.

Hereinafter, various aspects of the present disclosure will be collectively described as Appendices.

### (Appendix 1)

A semiconductor device comprising:
a semiconductor layer having a first conductivity type;
a semiconductor element provided in the semiconductor layer;
an impurity region having a second conductivity type and selectively provided in an upper portion of an outer peripheral portion of the semiconductor layer that surrounds the semiconductor element;
a first insulating film provided on the semiconductor layer, having a first opening that exposes the impurity region, and containing SiO₂ as a main component;
a second insulating film provided on the first insulating film, having a second opening that exposes the impurity region, and containing SiO₂ as a main component; and
a semi-insulating film provided on the second insulating film and connected to the impurity region via the first opening and the second opening,
wherein the impurity region includes at least one of a guard ring and a floating ring, and
a width of the second opening is larger than a width of the first opening.

### (Appendix 2)

The semiconductor device according to Appendix 1, wherein
an end of the first opening located close to an outside of the semiconductor layer is located closer to the outside of the semiconductor layer than an end of the impurity region located close to the outside of the semiconductor layer is.

### (Appendix 3)

The semiconductor device according to Appendix 1 or 2, wherein
the impurity region includes the guard ring and the floating ring,
the first opening is provided across the guard ring and the floating ring, and
the semi-insulating film is connected to the guard ring and the floating ring.

### (Appendix 4)

The semiconductor device according to any one of Appendices 1 to 3, further comprising
a moisture-resistant insulating film provided on the semi-insulating film.

### (Appendix 5)

The semiconductor device according to any one of Appendices 1 to 4, wherein
a first portion of the first insulating film located under the second opening is thinner than a second portion of the first insulating film other than the first portion.

### (Appendix 6)

The semiconductor device according to any one of Appendices 1 to 5, wherein
a density of the second insulating film is smaller than a density of the first insulating film.

### (Appendix 7)

The semiconductor device according to any one of Appendices 1 to 5, wherein
each of the first insulating film and the second insulating film further contains phosphorus, and
a concentration of phosphorus in the second insulating film is higher than a concentration of phosphorus in the first insulating film.

### (Appendix 8)

A method of manufacturing the semiconductor device according to any one of Appendices 1 to 7, comprising:
forming the first insulating film by thermal oxidation;
forming the second insulating film by chemical vapor deposition;
forming the first opening and the second opening in parallel with the first insulating film and the second insulating film, respectively, by wet etching.

### (Appendix 9)

A semiconductor device comprising:
a semiconductor layer having a first conductivity type;
a semiconductor element provided in the semiconductor layer;
an impurity region having a second conductivity type and selectively provided in an upper portion of an outer peripheral portion of the semiconductor layer that surrounds the semiconductor element;
a first insulating film provided on the semiconductor layer and having a first opening that exposes the impurity region;
a non-metallic film provided on the first insulating film, having a second opening that exposes the impurity region, and having an insulating property or a semi-insulating property; and
a semi-insulating film provided on the non-metallic film and connected to the impurity region via the first opening and the second opening, wherein
the impurity region includes a floating ring, and
a width of the second opening is smaller than a width of the first opening.

### (Appendix 10)

A semiconductor device comprising:
a semiconductor layer having a first conductivity type;
a semiconductor element provided in the semiconductor layer;
an impurity region having a second conductivity type and selectively provided in an upper portion of an outer peripheral portion of the semiconductor layer that surrounds the semiconductor element;
a first insulating film provided on the semiconductor layer and having a first opening that exposes the impurity region;
a second insulating film provided on the first insulating film and having a second opening that exposes the impurity region;
a non-metallic film provided on the second insulating film, having a third opening that exposes the impurity region, and having an insulating property or a semi-insulating property; and
a semi-insulating film provided on the non-metallic film and connected to the impurity region via the first opening, the second opening, and the third opening, wherein
the impurity region includes a floating ring,
a width of the second opening is larger than a width of the first opening, and
a width of the third opening is smaller than the width of the second opening.

### (Appendix 11)

The semiconductor device according to Appendix 9 or 10, wherein
the impurity region includes a plurality of the floating rings,
the first opening is provided across the plurality of the floating rings, and
the semi-insulating film is connected to the plurality of the floating rings.

### (Appendix 12)

The semiconductor device according to Appendix 9 or 10, wherein
the impurity region further includes a guard ring,
the first opening is provided across the guard ring and the floating ring, and
the semi-insulating film is connected to the guard ring and the floating ring.

### (Appendix 13)

The semiconductor device according to any one of Appendices 9 to 12, wherein
an end of the first opening located close to an outside of the semiconductor layer is located closer to the outside of the semiconductor layer than an end of the impurity region located close to the outside of the semiconductor layer is.

### (Appendix 14)

The semiconductor device according to any one of Appendices 9 to 13, further comprising
a moisture-resistant insulating film provided on the semi-insulating film.

### (Appendix 15)

A method of manufacturing the semiconductor device according to Appendix 9, comprising:
forming the first insulating film by thermal oxidation;
forming the non-metallic film having a wet etching speed lower than a wet etching speed of the first insulating film by chemical vapor deposition;
forming the second opening in the non-metallic film by dry etching; and
forming the first opening in the first insulating film by wet etching.

### (Appendix 16)

A method of manufacturing the semiconductor device according to Appendix 10, comprising:
forming the first insulating film by thermal oxidation;
forming the second insulating film by chemical vapor deposition;
forming the non-metallic film having a wet etching speed lower than wet etching speeds of the first insulating film and the second insulating film by chemical vapor deposition;
forming the third opening in the non-metallic film by dry etching; and
forming the first opening and the second opening in parallel with the first insulating film and the second insulating film, respectively, by wet etching.

While the disclosure has been shown and described in detail, the foregoing description is in all aspects illustrative and not restrictive. It is therefore understood that numerous modifications and variations can be devised.

What is claimed is:

1. A semiconductor device comprising:
a semiconductor layer having a first conductivity type;
a semiconductor element provided in the semiconductor layer;
an impurity region having a second conductivity type and selectively provided in an upper portion of an outer peripheral portion of the semiconductor layer that surrounds the semiconductor element;
a first insulating film provided on the semiconductor layer, having a first opening that exposes the impurity region, and containing SiO₂ as a main component;
a second insulating film provided on the first insulating film, having a second opening that exposes the impurity region, and containing SiO₂ as a main component; and
a semi-insulating film provided on the second insulating film and connected to the impurity region via the first opening and the second opening,
wherein the impurity region includes at least one of a guard ring and a floating ring, and
a width of the second opening is larger than a width of the first opening.

2. The semiconductor device according to claim 1, wherein an end of the first opening located close to an outside of the semiconductor layer is located closer to the outside of the semiconductor layer than an end of the impurity region located close to the outside of the semiconductor layer is.

3. The semiconductor device according to claim 1, wherein
the impurity region includes the guard ring and the floating ring,
the first opening is provided across the guard ring and the floating ring, and
the semi-insulating film is connected to the guard ring and the floating ring.

4. The semiconductor device according to claim 1, further comprising a moisture-resistant insulating film provided on the semi-insulating film.

5. The semiconductor device according to claim 1, wherein a first portion of the first insulating film located under the second opening is thinner than a second portion of the first insulating film other than the first portion.

6. The semiconductor device according to claim 1, wherein a density of the second insulating film is smaller than a density of the first insulating film.

7. The semiconductor device according to claim 1, wherein
each of the first insulating film and the second insulating film further contains phosphorus, and
a concentration of phosphorus in the second insulating film is higher than a concentration of phosphorus in the first insulating film.

8. A method of manufacturing the semiconductor device according to claim 1, comprising:
forming the first insulating film by thermal oxidation;
forming the second insulating film by chemical vapor deposition;
forming the first opening and the second opening in parallel with the first insulating film and the second insulating film, respectively, by wet etching.

9. A semiconductor device comprising:
a semiconductor layer having a first conductivity type;
a semiconductor element provided in the semiconductor layer;
an impurity region having a second conductivity type and selectively provided in an upper portion of an outer peripheral portion of the semiconductor layer that surrounds the semiconductor element;
a first insulating film provided on the semiconductor layer and having a first opening that exposes the impurity region;
a non-metallic film provided on the first insulating film, having a second opening that exposes the impurity region, and having an insulating property or a semi-insulating property; and
a semi-insulating film provided on the non-metallic film and connected to the impurity region via the first opening and the second opening,
wherein the impurity region includes a floating ring, and
a width of the second opening is smaller than a width of the first opening.

10. A semiconductor device comprising:
a semiconductor layer having a first conductivity type;
a semiconductor element provided in the semiconductor layer;
an impurity region having a second conductivity type and selectively provided in an upper portion of an outer peripheral portion of the semiconductor layer that surrounds the semiconductor element;
a first insulating film provided on the semiconductor layer and having a first opening that exposes the impurity region;
a second insulating film provided on the first insulating film and having a second opening that exposes the impurity region;
a non-metallic film provided on the second insulating film, having a third opening that exposes the impurity region, and having an insulating property or a semi-insulating property; and
a semi-insulating film provided on the non-metallic film and connected to the impurity region via the first opening, the second opening, and the third opening,
wherein the impurity region includes a floating ring,
a width of the second opening is larger than a width of the first opening, and
a width of the third opening is smaller than the width of the second opening.

11. The semiconductor device according to claim 9, wherein
the impurity region includes a plurality of the floating rings,
the first opening is provided across the plurality of the floating rings, and
the semi-insulating film is connected to the plurality of the floating rings.

12. The semiconductor device according to claim 9, wherein
the impurity region further includes a guard ring,
the first opening is provided across the guard ring and the floating ring, and
the semi-insulating film is connected to the guard ring and the floating ring.

13. The semiconductor device according to claim 9, wherein an end of the first opening located close to an outside of the semiconductor layer is located closer to the outside of the semiconductor layer than an end of the impurity region located close to the outside of the semiconductor layer is.

14. The semiconductor device according to claim 9, further comprising a moisture-resistant insulating film provided on the semi-insulating film.

15. A method of manufacturing the semiconductor device according to claim 9, comprising:
forming the first insulating film by thermal oxidation;
forming the non-metallic film having a wet etching speed lower than a wet etching speed of the first insulating film by chemical vapor deposition;
forming the second opening in the non-metallic film by dry etching; and
forming the first opening in the first insulating film by wet etching.

16. A method of manufacturing the semiconductor device according to claim 10, comprising:
forming the first insulating film by thermal oxidation;
forming the second insulating film by chemical vapor deposition;
forming the non-metallic film having a wet etching speed lower than wet etching speeds of the first insulating film and the second insulating film by chemical vapor deposition;
forming the third opening in the non-metallic film by dry etching; and
forming the first opening and the second opening in parallel with the first insulating film and the second insulating film, respectively, by wet etching.
